(19) United States
(12) Patent Application Publication
(10) Pub. No.: US 2023/0273098 A1
(43) Pub. Date: Aug. 31, 2023

(54) Method for Preparing TEM Sample

(71) Applicant: Shanghai Huali Integrated Circuit Corporation, Shanghai (CN)

(72) Inventors: Qiang Chen, Shanghai (CN); Yanrong Qiu, Shanghai (CN); Jinde Gao, Shanghai (CN)

(73) Assignee: Shanghai Huali Integrated Circuit Corporation, Shanghai (CN)

(21) Appl. No.: 18/151,045

(22) Filed: Jan. 6, 2023

(30) Foreign Application Priority Data
Feb. 28, 2022 (CN) 202210185188.6

(51) Int. Cl. G01N 1/28; H01J 37/31

(52) U.S. Cl. CPC G01N 1/286; H01J 37/31; G01N 2001/2873

(57) ABSTRACT

The present application discloses a method for preparing a TEM sample, comprising: step 1, forming a first protective layer to non-full fill a deep trench; step 2, performing a first time of front and rear side cutting using a FIB, so as to form the TEM sample having a first thickness, and a via in the deep trench is exposed from the front side and the rear side of the TEM sample; step 3, forming a second material layer, which fully fills the exposed via from the front side and the rear side of the TEM sample; and step 4, performing a second time of front and rear side cutting of a target area on the chip sample using the FIB, so as to reduce the thickness of the TEM sample to a target thickness.

### CROSS-REFERENCES TO RELATED APPLICATIONS

This application claims priority to Chinese Patent Application No. CN 202210185188.6, filed on Feb. 28, 2022, the disclosure of which is incorporated herein by reference in its entirety.

### TECHNICAL FIELD

The present application relates to a method for manufacturing a semiconductor integrated circuit, in particular to a method for preparing a transmission electron microscope (TEM) sample.

### BACKGROUND

TEM is one of the indispensable research and analysis tools in the process of integrated circuit production. As the manufacturing process gradually develops to the nanometer level, the device dimension becomes increasingly small. Due to the advantages of high resolution and high precision, the TEM is applied in aspects such as failure analysis increasingly widely. Preparing a TEM sample by means of Focused Ion Beam (FIB) precise positioning is one of the most important preparation means in the field of semiconductors.

The preparation of the TEM sample using the FIB is based on a chip sample of a chip. During the preparation of the TEM sample of the chip using the FIB, in the case of a difference in the thickness or material of the chip sample, in particular the case of a via on the chip sample, an ion beam scratch may be produced, which is also referred to as a curtain effect. These ion beam scratches may affect the quality of TEM imaging, and if becoming serious, may even cause damage to the TEM sample in preparation of an ultrathin TEM sample.

When there is a deep trench structure in the chip sample, it is easy to produce ion beam scratches in sample preparation using an existing method. In particular, when the material of a target structure is fragile and vulnerable to the electron beam or thermal stress, the sample preparation becomes more difficult.

The existing method for preparing a TEM sample includes the following steps.

Step 1. Referring to FIG. 1A, a chip sample 101 having a deep trench 102 is provided.

Generally, the chip sample 101 includes a semiconductor substrate and a semiconductor device layer formed on a front side of the semiconductor substrate. The deep trench 102 is located on the semiconductor device layer.

The semiconductor substrate includes a silicon substrate.

The thickness of the chip sample 101 is greater than 500 nm. The chip sample 101 is obtained by cutting and thinning a wafer composed of the semiconductor substrate.

The chip sample 101 includes a plurality of deep trenches 102, and all the deep trenches 102 are arranged in parallel.

In FIG. 1A, the length direction of the deep trench 102 is a y direction, the width direction of the deep trench 102 is an x direction, and the deep trenches 102 are arranged at intervals along the x direction. The dashed line box 103 represents a target area for forming the TEM sample, that is, an area to be analyzed is located in the dashed line box 103.

FIG. 1B is a sectional view corresponding to FIG. 1A, wherein a section is an xz plane.

Referring to FIG. 2A, a protective layer 104 is formed, that is, filling with the protective layer 104 starts from the top. Referring to FIG. 2B, the protective layer 104 fills the deep trench 102 from the top of the chip sample 101, and the protective layer 104 further extends to the top surface of the chip sample 101 outside the deep trench 102.

A first value is a maximum aspect ratio of a trench fully filled with the protective layer 104, and the aspect ratio of the deep trench 102 is greater than the first value. The protective layer 104 does not fully fill the deep trench 102, and a via 105 produced by non-full filling is formed in the deep trench 102.

Step 2: Referring to FIG. 3A, front and rear side cutting of a target area on the chip sample 101 for forming a TEM sample is performed using a FIB, so as to form a TEM sample 106 having a target thickness.

A front side 1061 and a rear side 1062 of the TEM sample 106 both perpendicularly intersect with an extension direction of the deep trench 102 as shown in FIG. 3A. In this way, referring to FIG. 3B, the via 105 in the deep trench 102 may be exposed from the front side 1061 and the rear side 1062 of the TEM sample 106. In the process of the front and rear side cutting, the curtain effect may occur at the bottom of the via 105, thus forming an ion beam scratch 107.

FIG. 4 is a picture of the TEM sample prepared by means of the existing method for preparing a TEM sample. FIG. 4 corresponds to a picture of the TEM sample 106 in FIG. 3B. It can be seen that after a protective layer 104a fills the deep trench, a via 105a is formed, and an ion beam scratch 107a is formed at the bottom of the via 105a.

### BRIEF SUMMARY

According to some embodiments in this application, the present application is to provide a method for preparing a TEM sample, so as to reduce or eliminate ion beam scratches produced during a sample preparation process for a chip sample having a deep trench, thereby eliminating damages caused by the ion beam scratches in the TEM sample and improving the quality of the TEM sample and the success rate of sample preparation.

The method for preparing a TEM sample provided by the present application includes the following steps:
step 1, providing a chip sample having a deep trench, and forming a first protective layer, the first protective layer filling the deep trench from the top of the chip sample, and the first protective layer further extending to the top surface of the chip sample outside the deep trench, wherein
   a first value is a maximum aspect ratio of a trench fully filled with the first protective layer, the aspect ratio of the deep trench is greater than the first value, the first protective layer does not fully fill the deep trench, and a via produced by non-full filling is formed in the deep trench;
step 2, performing, using a FIB, the first time of front and rear side cutting of a target area on the chip sample for forming a TEM sample, so as to form the TEM sample having a first thickness, the first thickness being greater than a target thickness, wherein a front side and a rear side of the TEM sample both intersect with an extension direction of the deep trench, and the via in the deep trench is exposed from the front side and the rear side of the TEM sample;
step 3, forming a second material layer, the second material layer fully filling the exposed via from the front side and the rear side of the TEM sample; and
step 4, performing the second time of front and rear side cutting of the target area on the chip sample using the FIB, so as to reduce the thickness of the TEM sample to the target thickness.

In some cases, the chip sample includes a semiconductor substrate and a semiconductor device layer formed on a front side of the semiconductor substrate, and the deep trench is located on the semiconductor device layer.

In some cases, the chip sample includes a plurality of deep trenches, and all the deep trenches are arranged in parallel.

In some cases, in the semiconductor device layer, a structure having the deep trench includes:
deep trench isolation;
an arrangement structure of polysilicon wires;
an arrangement structure of fins; and
an arrangement structure of metal wires.

In some cases, in step 1, the first protective layer is formed by means of an electron beam assisted deposition process or a colloid coating process.

In some cases, in step 2, the front side and the rear side of the TEM sample both perpendicularly intersect with the extension direction of the deep trench.

In some cases, in step 2, a cutting direction of the first time of front and rear side cutting is a direction from the top surface to the bottom surface of the chip sample.

In some cases, the first thickness is 100-300 nm.

In some cases, the target thickness is 30-80 nm.

In some cases, in step 3, the second material layer is formed by means of an electron beam assisted deposition process.

In some cases, the semiconductor substrate includes a silicon substrate.

In some cases, the material of the first protective layer includes a metal material.

In some cases, the material of the second material layer includes a metal material.

In some cases, in step 1, the thickness of the chip sample is greater than 500 nm.

In some cases, the chip sample is obtained by cutting and thinning a wafer composed of the semiconductor substrate

In the present application, for the chip sample having the deep trench, after the top of the chip sample is filled with the first protective layer, the front and rear side cutting of the TEM sample is divided. Before the TEM sample is thinned to the target thickness, the via formed after filling the deep trench with the first protective layer is exposed from the front side and the rear side of the TEM sample. A step of side filling for the TEM sample is added, and the via in the deep trench of the TEM sample is fully filled by means of the side filling. Then front and rear side cutting of the TEM sample continues, i.e., the second time of front and rear side cutting. Before the second time of front and rear side cutting, the deep trench in the TEM sample area is fully filled with the first protective layer and the second material layer, and thus no ion beam scratch is produced during the second time of front and rear side cutting. Therefore, the present application can reduce or eliminate ion beam scratches produced during a sample preparation process for a chip sample having a deep trench, thereby eliminating damages caused by the ion beam scratches in the TEM sample and improving the quality of the TEM sample and the success rate of sample preparation.

In addition, the second material layer of the present application can be realized by means of the electron beam assisted deposition process, while the first time of front and rear side cutting and the second time of front and rear side cutting are both performed by using the FIB. Both electron beam assisted deposition and FIB cutting can be realized in the same FIB system, so the present application is also characterized by simple operation and low process cost.

### BRIEF DESCRIPTION OF THE DRAWINGS

The present application is described in detail below with reference to the drawings and specific implementations

FIG. 1A is a top view of a chip sample provided in an existing method for preparing a TEM sample.

FIG. 1B is a sectional view corresponding to FIG. 1A.

FIG. 2A is a top view of the chip sample provided after filling with a protective layer in the existing method for preparing a TEM sample.

FIG. 2B is a sectional view corresponding to FIG. 2A.

FIG. 3A is a top view of the chip sample provided after front and rear side cutting of the TEM sample in the existing method for preparing a TEM sample.

FIG. 3B is a sectional view corresponding to FIG. 3A.

FIG. 4 is a picture of the TEM sample prepared by the existing method for preparing a TEM sample.

FIG. 5 is a flowchart of a method for preparing a TEM sample according to an embodiment of the present application.

FIG. 6A is a top view of a chip sample provided in step 1 of the method for preparing a TEM sample according to an embodiment of the present application.

FIG. 6B is a sectional view corresponding to FIG. 6A.

FIG. 7A is a top view of the chip sample provided after filling the top with a first protective layer in step 1 of the method for preparing a TEM sample according to an embodiment of the present application.

FIG. 7B is a sectional view corresponding to FIG. 7A.

FIG. 8A is a top view of the chip sample provided after the first time of front and rear side cutting in step 2 of the method for preparing a TEM sample according to an embodiment of the present application.

FIG. 8B is a sectional view corresponding to FIG. 8A.

FIG. 9A is a top view of the chip sample provided after side filling with a first material in step 3 of the method for preparing a TEM sample according to an embodiment of the present application.

FIG. 9B is a sectional view corresponding to FIG. 9A.

FIG. 10A is a top view of the chip sample provided after the second time of front and rear side cutting in step 4 of the method for preparing a TEM sample according to an embodiment of the present application.

FIG. 10B is a sectional view corresponding to FIG. 10A.

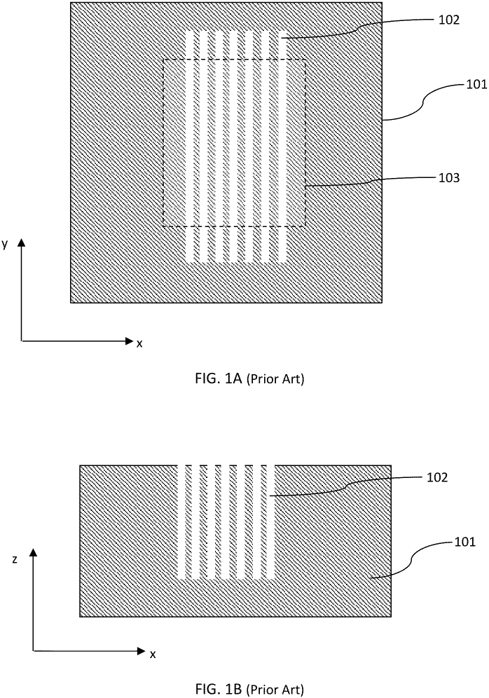

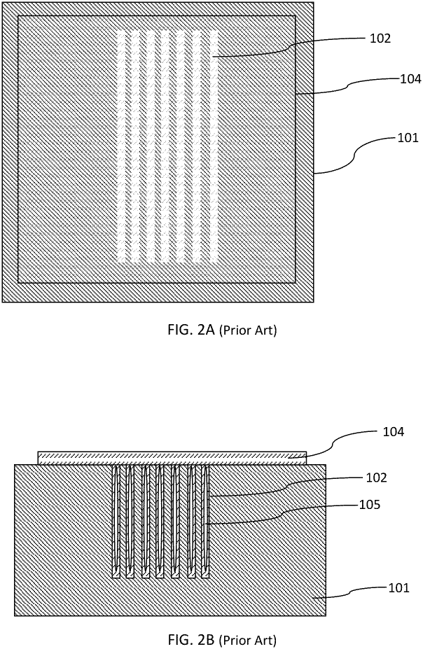

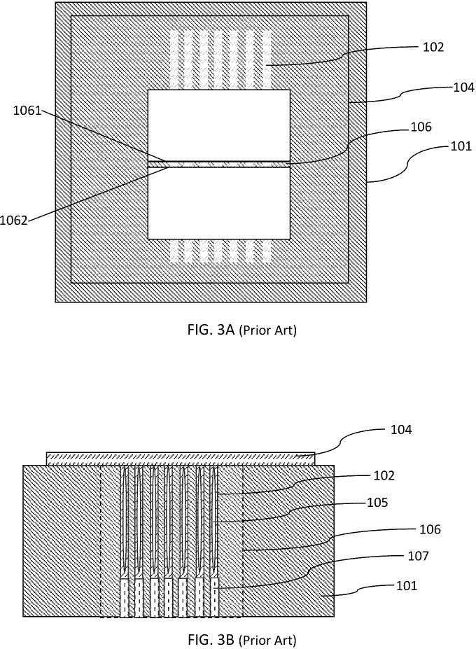

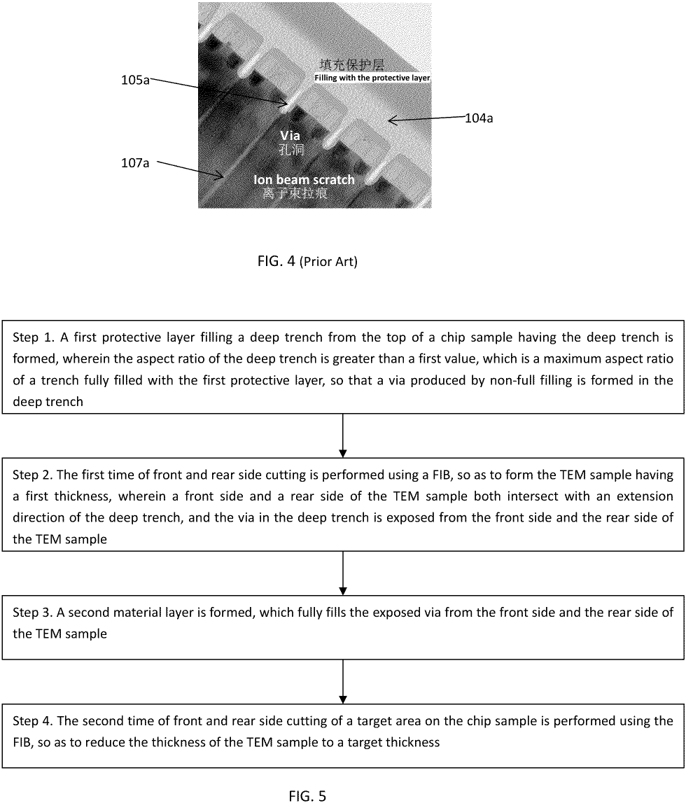

### DETAILED DESCRIPTION OF THE DISCLOSURE

FIG. 5 is a flowchart of a method for preparing a TEM sample according to an embodiment of the present application. The method for preparing a TEM sample according to an embodiment of the present application includes the following steps.

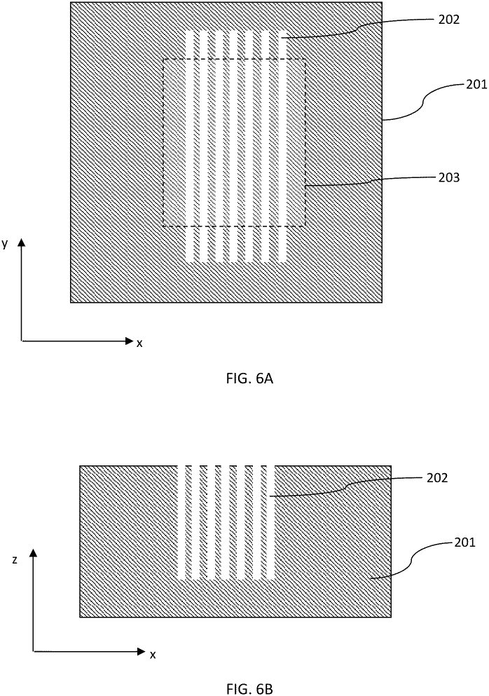

Step 1. Referring to FIG. 6A, a chip sample 201 having a deep trench 202 is provided.

In this embodiment of the present application, the chip sample 201 includes a semiconductor substrate and a semiconductor device layer formed on a front side of the semiconductor substrate. The deep trench 202 is located on the semiconductor device layer.

The semiconductor substrate includes a silicon substrate.

The thickness of the chip sample 201 is greater than 500 nm. The chip sample 201 is obtained by cutting and thinning a wafer composed of the semiconductor substrate.

The chip sample 201 includes a plurality of the deep trenches 202, and all the deep trenches 202 are arranged in parallel.

In some embodiments, a structure having the deep trench 202 is deep trench isolation.

In some embodiments, the structure having the deep trench 202 is an arrangement structure of polysilicon wires. The deep trench 202 is formed between the polysilicon wires.

In some embodiments, the structure having the deep trench 202 is an arrangement structure of fins. The deep trench 202 is formed between the fins.

In some embodiments, the structure having the deep trench 202 is an arrangement structure of metal wires. The deep trench 202 is formed between the metal wires.

In FIG. 6A, the length direction of the deep trench 202 is a y direction, the width direction of the deep trench 202 is an x direction, and the deep trenches 202 are arranged at intervals along the x direction. The dashed line box 203 represents a target area for forming the TEM sample, that is, an area to be analyzed is located in the dashed line box 203.

FIG. 6B is a sectional view corresponding to FIG. 6A, wherein a section is an xz plane.

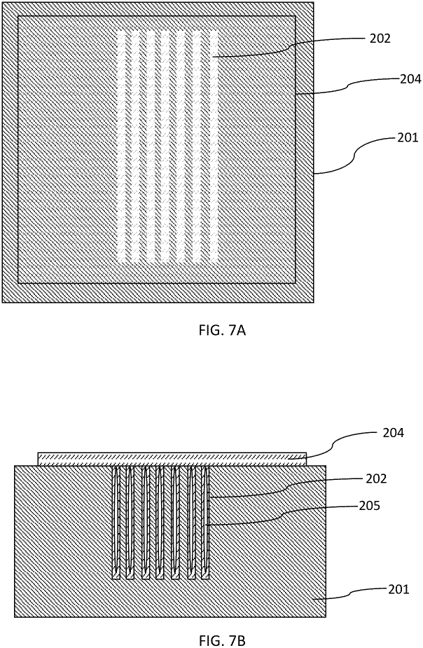

Referring to FIG. 7A, a first protective layer 204 is formed. Referring to FIG. 7B, the first protective layer 204 fills the deep trench 202 from the top of the chip sample 201, and the first protective layer 204 further extends to the top surface of the chip sample 201 outside the deep trench 202.

A first value is a maximum aspect ratio of a trench fully filled with the first protective layer 204, and the aspect ratio of the deep trench 202 is greater than the first value. The first protective layer 204 does not fully fill the deep trench 202, and a via 205 produced by non-full filling is formed in the deep trench 202.

In some embodiments, the first protective layer 204 is formed by means of an electron beam assisted deposition process. In this case, the first protective layer 204 can be directly formed in a FIB system. In other embodiments, the first protective layer 204 is formed by means of a colloidal coating process.

The material of the first protective layer 204 includes a metal material.

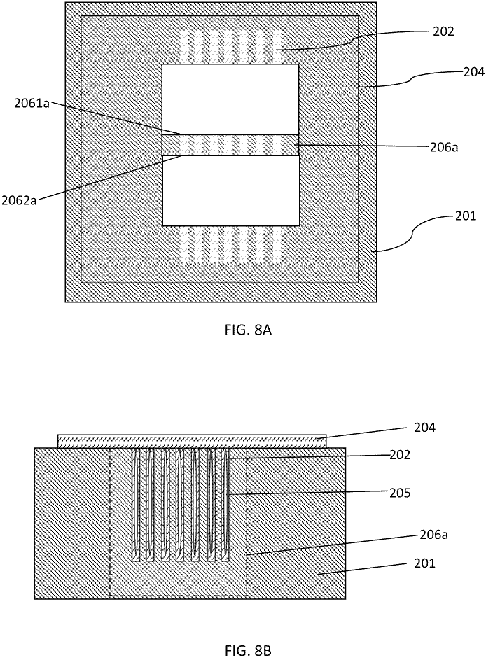

Step 2. Referring to FIG. 8A, the first time of front and rear side cutting of a target area on the chip sample 201 for forming a TEM sample is performed using a FIB, so as to form the TEM sample 206a having a first thickness, the first thickness being greater than a target thickness, wherein a front side 2061a and a rear side 2062a of the TEM sample 206a both intersect with an extension direction of the deep trench 202, and referring to FIG. 8A, the via 205 in the deep trench 202 is exposed from the front side 2061a and the rear side 2062a of the TEM sample 206a.

In FIG. 8A, the blank area on both sides of the TEM sample 206a is an area to be removed by the first time of front and rear side cutting.

In some example embodiments, the front side and the rear side of the TEM sample both perpendicularly intersect with the extension direction of the deep trench 202.

In some embodiments, a cutting direction of the first time of front and rear side cutting is a direction from the top surface to the bottom surface of the chip sample 201.

The first thickness is 100-300 nm.

The target thickness is 30-80 nm.

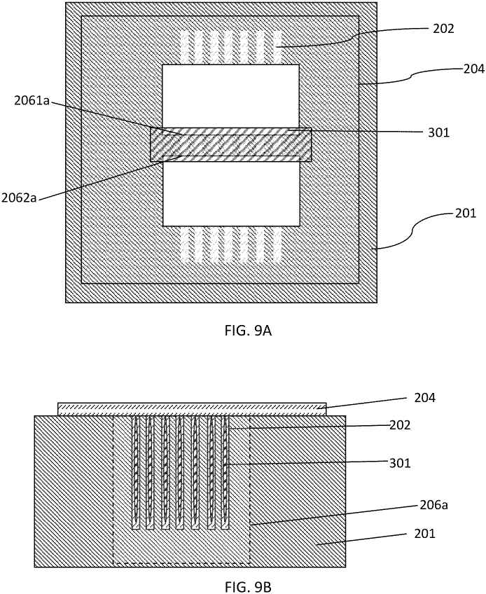

Step 3. Referring to FIG. 9A, a second material layer 301 is formed. Referring to FIG. 9B, the second material layer 301 fully fills the exposed via 205 from the front side 2061a and the rear side 2062a of the TEM sample.

In some embodiments, the second material layer 301 is formed by means of an electron beam assisted deposition process. In this case, the second material layer 301 can be directly formed in the FIB system, and the second material layer 301 is formed by means of a low energy side filling process.

The material of the second material layer 301 includes a metal material.

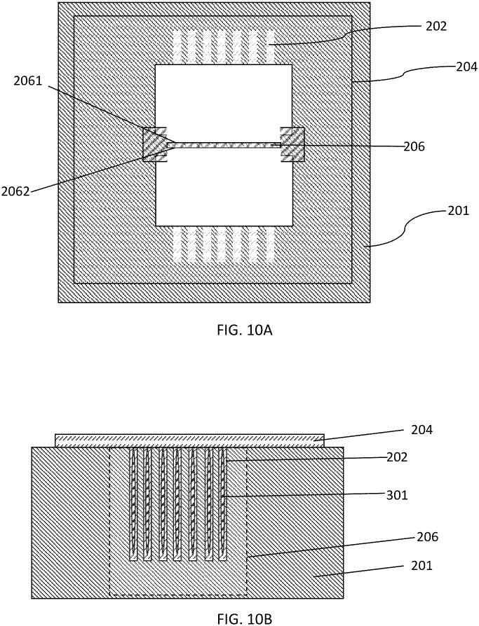

Step 4. Referring to FIG. 10A, the second time of front and rear side cutting of the target area on the chip sample 201 is performed using the FIB, so as to reduce the thickness of the TEM sample 206 to the target thickness. The TEM sample reaching the target thickness is separately marked with mark 206, and the front side of the TEM sample 206 is marked with mark 2061 and the rear side is marked with mark 2062.

In the process of the second time of front and rear side cutting, since both the front side 2061 and rear side 2062 of the TEM sample 206 have no vias, ion beam scratches can be reduced or eliminated. FIG. 10B shows that no ion beam scratch is produced.

In the present application, for the chip sample 201 having the deep trench 202, after the top of the chip sample 201 is filled with the first protective layer 204, the front and rear side cutting of the TEM sample is divided. Before the TEM sample is thinned to the target thickness, the via 205 formed after filling the deep trench 202 with the first protective layer 204 is exposed from the front side 2061a and the rear side 2062a of the TEM sample 206a. A step of side filling for the TEM sample 206a is added, and the via 205 in the deep trench 202 of the TEM sample 206a is fully filled by means of the side filling. Then front and rear side cutting of the TEM sample continues, i.e., the second time of front and rear side cutting. Before the second time of front and rear side cutting, the deep trench 202 in the TEM sample area is fully filled with the first protective layer 204 and the second material layer 301, and thus no ion beam scratch is produced during the second time of front and rear side cutting. Therefore, the embodiment of the present application can reduce or eliminate ion beam scratches produced during a sample preparation process for the chip sample 201 having the deep trench 202, thereby eliminating damages caused by the ion beam scratches in the TEM sample 206 and improving the quality of the TEM sample 206 and the success rate of sample preparation.

In addition, the second material layer 301 of the embodiment of the present application can be realized by means of the electron beam assisted deposition process, while the first time of front and rear side cutting and the second time of front and rear side cutting are both performed by using the FIB. Both electron beam assisted deposition and FIB cutting can be realized in the same FIB system, so the present application is also characterized by simple operation and low process cost.

The present application is described in detail above via specific embodiments, which, however, do not intended to limit the present application. Without departing from the principle of the present application, those skilled in the art can also make many other changes and improvements, which shall also be considered as the scope of protection the present application.

What is claimed is:

1. A method for preparing a transmission electron microscope (TEM) sample, comprising the following steps:
step 1, providing a chip sample having a deep trench, and forming a first protective layer, the first protective layer filling the deep trench from a top of the chip sample, and the first protective layer further extending to a top surface of the chip sample outside the deep trench, wherein
a first value is a maximum aspect ratio of a trench fully filled with the first protective layer, an aspect ratio of the deep trench is greater than the first value, the first protective layer does not fully fill the deep trench, and a via produced by non-full filling is formed in the deep trench;
step 2, performing, using a focused ion beam (FIB), a first time of front and rear side cutting of a target area on the chip sample for forming the TEM sample, so as to form the TEM sample having a first thickness, the first thickness being greater than a target thickness, wherein a front side and a rear side of the TEM sample both intersect with an extension direction of the deep trench, and the via in the deep trench is exposed from the front side and the rear side of the TEM sample;
step 3, forming a second material layer, the second material layer fully filling the exposed via from the front side and the rear side of the TEM sample; and
step 4, performing a second time of front and rear side cutting of the target area on the chip sample using the FIB, so as to reduce a thickness of the TEM sample to the target thickness.

2. The method for preparing the TEM sample according to claim 1, wherein the chip sample comprises a semiconductor substrate and a semiconductor device layer formed on a front side of the semiconductor substrate, and the deep trench is located on the semiconductor device layer.

3. The method for preparing the TEM sample according to claim 2, wherein the chip sample comprises a plurality of deep trenches, and all of the deep trenches are arranged in parallel.

4. The method for preparing the TEM sample according to claim 3, wherein, in the semiconductor device layer, a structure having the deep trench comprises:
deep trench isolation;
an arrangement structure of polysilicon wires;
an arrangement structure of fins; and
an arrangement structure of metal wires.

5. The method for preparing the TEM sample according to claim 1, wherein, in step 1, the first protective layer is formed by means of an electron beam assisted deposition process or a colloid coating process.

6. The method for preparing the TEM sample according to claim 1, wherein, in step 2, the front side and the rear side of the TEM sample both perpendicularly intersect with the extension direction of the deep trench.

7. The method for preparing the TEM sample according to claim 1, wherein, in step 2, a cutting direction of the first time of front and rear side cutting is a direction from the top surface to a bottom surface of the chip sample.

8. The method for preparing the TEM sample according to claim 1, wherein the first thickness is 100-300 nm.

9. The method for preparing the TEM sample according to claim 8, wherein the target thickness is 30-80 nm.

10. The method for preparing the TEM sample according to claim 1, wherein, in step 3, the second material layer is formed by means of an electron beam assisted deposition process.

11. The method for preparing the TEM sample according to claim 2, wherein the semiconductor substrate comprises a silicon substrate.

12. The method for preparing the TEM sample according to claim 1, wherein a material of the first protective layer comprises a metal material.

13. The method for preparing the TEM sample according to claim 1, wherein a material of the second material layer comprises a metal material.

14. The method for preparing the TEM sample according to claim 1, wherein, in step 1, a thickness of the chip sample is greater than 500 nm.

15. The method for preparing the TEM sample according to claim 14, wherein the chip sample is obtained by cutting and thinning a wafer composed of a semiconductor substrate.
